(19) United States
(12) Patent Application Publication
(10) Pub. No.: US 2024/0290901 A1
(43) Pub. Date: Aug. 29, 2024

(54) HIGHLY-EFFICIENT FULL VAN DER WAALS 1D p-Te/2D n-Bi2O2Se HETERODIODES WITH NANOSCALE ULTRA-PHOTOSENSITIVE CHANNELS

(71) Applicant: City University of Hong Kong, Hong Kong (CN)

(72) Inventors: Chung Yin Johnny HO, Hong Kong (CN); Weijun WANG, Hong Kong (CN); You MENG, Hong Kong (CN); Wei WANG, Hong Kong (CN)

(73) Assignee: City University of Hong Kong, Hong Kong (CN)

(21) Appl. No.: 18/174,359

(22) Filed: Feb. 24, 2023

(51) Int. Cl. H01L 31/109; H01L 31/0336; H01L 31/0352; H01L 31/18

(52) U.S. Cl. CPC H01L 31/109; H01L 31/0336; H01L 31/035209; H01L 31/035227; H01L 31/1896

(57) ABSTRACT

Continuous miniaturization of semiconductor devices is the key to boosting modern electronics development. However, such downscaling strategy has been rarely utilized in photoelectronics and photovoltaics. Here, in this work, a full-vdWs 1D p-Te/2D n-Bi₂O₂Se heterodiode with a rationally-designed nanoscale ultra-photosensitive channel is reported. Enabled by the dangling bond-free mixed-dimensional vdWs integration, the Te/Bi₂O₂Se type-II diodes show a high rectification ratio of 3.6×10⁴. Operating with 100 mV reverse bias or in a self-power mode, the photodiodes demonstrated excellent photodetection performances, including high responsivities of 130 A W⁻¹ (100 mV bias) and 768.8 mA W⁻¹ (self-power mode), surpassing most of the reports of other heterostructures. More importantly, a superlinear photoelectric conversion phenomenon is uncovered in these nanoscale full-vdWs photodiodes, in which a model based on the in-gap trap-assisted recombination is proposed for this superlinearity. All these results provide valuable insights in light-matter interactions for further performance enhancement of photoelectronic devices.

### FIELD OF THE INVENTION

The present invention relates generally to semiconductors and nanoscale ultra-photosensitive channels. More specifically, but not exclusively, the present invention concerns highly-efficient full van der Waals (vdW) 1D p-Te/2D n-Bi₂O₂Se heterodiodes with nanoscale ultra-photosensitive channels.

### BACKGROUND OF THE INVENTION

Continuous device miniaturization supports the development of modern semiconductor electronics. However, such downscaling strategy in traditional silicon-based field-effect transistors (FETs) in the large-scale integrated circuit has been rarely utilized in photoelectronics and photovoltaics. This has restricted the optoelectronic components for possessing higher operation speed, better noise tolerance, and lower power consumption, thus impeding their massive integration. Therefore, to fulfill the downscaling requirements of optoelectronics, all the critical factors governing the device functionality must be carefully reformed, including materials, architectures, and concepts.

Although 2D/2D materials heterostructures have witnessed the downscaling of photosensitive channels ultimately to the nanoscale thickness, they may suffer from poor light absorption efficiency and low responsivity due to the ultrathin nature. In contrast, the 1D/2D materials heterostructures provide the complementary features of non-degradation of light absorption powered by the antenna effects of nanowires (NWs). Moreover, as the sensitive areas downsize, the intrinsic photoresponse speed can be promoted, benefiting from the optimized resistance-capacitance time constant. Most conventional 1D/2D heterojunctions utilized the non-vdWs semiconductor NWs, such as ZnO and Sb₂Se₃, in which the surface dangling bond inevitably gives rise to the defect-induced performance degradation.

Thus, what is needed is a highly-efficient full-vdWs 1D p-Te/2D n-Bi₂O₂Se heterodiode that is developed to maximize the performance of the downsized nanoscale ultra-photosensitive channel, which shows several advances compared with conventional low-dimensional heterojunction photodetectors. Specifically, a recorded ratification ratio (RF) is obtained, as the dangling-bond-free interface of the full-vdWs 1D p-Te/2D n-Bi₂O₂Se heterodiodes utmostly minimizes the defect-induced performance degradation. The rationally designed nanoscale photosensitive channel of the optoelectronic devices optimizes the resistance-capacitance (RC) time constant, largely improving the response speed under low external potential. In addition, the full-vdWs 1D p-Te/2D n-Bi₂O₂Se heterodiode show significant advantages in light absorption efficiency, as they generally demonstrate non-degradation of light absorption powered by the antenna effects of NWs.

### SUMMARY OF THE INVENTION

Aspects of the present invention provide highly-efficient full van der Waals (vdW) 1D p-Te/2D n-Bi₂O₂Se heterodiodes with nanoscale ultra-photosensitive channels and a method for creating same.

In one aspect, provided herein is a method of forming heterodiodes including obtaining a first substrate with at least one nanosheet. The method also includes spin-coating a layer over the substrate and at least one nanosheet and peeling off the layer from the substrate removing the at least one coupled nanosheet and forming a peeled-off layer. The method further includes obtaining a second substrate with at least one nanowire fabricated on the second substrate and aligning the peeled-off layer with the second substrate. In addition, the method includes pressing the peeled-off layer to the second substrate and heating the peeled-off layer and the second substrate. Finally, the method includes removing the peeled-off layer from the second substrate leaving the at least one nanosheet on the second substrate forming at least one heterostructure.

In another aspect, provided herein is a 1D p-Te/2D n-Bi₂O₂Se heterodiode, including a nanowire, and a nanosheet positioned over at least a portion of the nanowire.

These, and other objects, features and advantages of this invention will become apparent from the following detailed description of the various aspects of the invention taken in conjunction with the accompanying drawings.

### BRIEF DESCRIPTION OF DRAWINGS

The accompanying drawings, which are incorporated in and constitute a part of the specification, illustrate embodiments of the invention and together with the detailed description herein, serve to explain the principles of the invention. The drawings are only for purposes of illustrating preferred embodiments and are not to be construed as limiting the invention. It is emphasized that, in accordance with the standard practice in the industry, various features are not drawn to scale. In fact, the dimensions of the various features may be arbitrarily increased or reduced for clarity of discussion. The foregoing and other objects, features and advantages of the invention are apparent from the following detailed description taken in conjunction with the accompanying drawings in which:

FIG. 1 shows the fabrication process of 1D Te nanowire/2D Bi₂O₂Se nanosheet heterojunction via a standard transfer process, in accordance with an aspect of the present disclosure;

FIG. 2A is an illustration of the crystal structure of Bi₂O₂Se nanosheets (NSs), in accordance with an aspect of the present disclosure;

FIG. 2B is scanning electron microscope (SEM) image of the as-grown Bi₂O₂Se NSs on mica synthesized by the chemical vapor deposition (CVD) method, in accordance with an aspect of the present disclosure;

FIG. 2C is a high resolution transmission electron microscopy (HRTEM) image of Bi₂O₂Se NSs indicating the d-spacings of 0.27 nm for (110) planes, in accordance with an aspect of the present disclosure;

FIG. 2D is an illustration of the crystal structure of Te NWs with helical atomic chains, in accordance with an aspect of the present disclosure;

FIG. 2E is a SEM image of the uniform Te NWs grown on mica via the CVD method, in accordance with an aspect of the present disclosure;

FIG. 2F is HRTEM characterization of the Te NWs shows an interplanar spacing distance of 0.38 nm, corresponding to the lattice spacing of (001) planes, in accordance with an aspect of the present disclosure;

FIG. 3A is an OM image of the full-vdWs 1D Te/2D Bi₂O₂Se heterojunction device, in accordance with an aspect of the present disclosure;

FIG. 3B is a Raman mapping of the A_{1g} peak of Bi₂O₂Se, in accordance with an aspect of the present disclosure;

FIG. 3C is a Raman mapping of the A₁ peak of Te in the overlapping heterojunction region, in accordance with an aspect of the present disclosure;

FIG. 3D is a Raman spectra graph of pure Te, Bi₂O₂Se, and their heterojunction region, in accordance with an aspect of the present disclosure;

FIG. 3E is a graph of the transfer characteristics of the device at distinct biases of 100 mV and 300 mV, respectively, in accordance with an aspect of the present disclosure;

FIG. 3F is a graph of I_{ds}-V_{ds} curves of the Te/Bi₂O₂Se device on linear and logarithmic scales in the bias range of −1 to 1V with zero gate voltage in the dark, in accordance with an aspect of the present disclosure;

FIG. 4A is a graph of logarithmic-scale I_{ds}-V_{ds} curves as a function of incident power densities measured in the dark and under 532 nm light, in accordance with an aspect of the present disclosure;

FIG. 4B is a graph of photoswitching characteristics measured at V_{ds}=−100 mV under 532 nm laser with different light power densities, mW cm⁻², in accordance with an aspect of the present disclosure;

FIG. 4C is a graph of time-resolved photoresponse shows fast photoswitching speeds at V_{ds}=−100 mV under 532 nm, in accordance with an aspect of the present disclosure;

FIG. 5A is an atomic force microscopy (AFM) topological morphology of the Te/Bi₂O₂Se heterojunction, in accordance with an aspect of the present disclosure;

FIG. 5B is a kelvin probe force microscopy (KPFM) image of the Te/Bi₂O₂Se heterojunction, in accordance with an aspect of the present disclosure;

FIG. 5C is an image of KPFM profile obtained along with the white dashed line in FIG. 5B, in accordance with an aspect of the present disclosure;

FIG. 5D is a graph of ultraviolet photoelectron spectrum (UPS) of Bi₂O₂Se NSs for evaluating work function and valence band edge, in accordance with an aspect of the present disclosure;

FIG. 5E is a schematic of the band diagram of the Te/Bi₂O₂Se heterojunction before contact, after contact, and at reverse bias when illuminated, in accordance with an aspect of the present disclosure;

FIG. 6A is a graph of photovoltaic photoswitching characteristics of the heterojunction under 532 nm laser with different light power densities, in accordance with an aspect of the present disclosure;

FIG. 6B is a graph of time-resolved photoresponse of laser power intensity in the photovoltaic mode under 532 nm laser, in accordance with an aspect of the present disclosure; and

FIG. 6C is a graph of responsivity and detectivity of the device under varying light intensities, in accordance with an aspect of the present disclosure.

### DETAILED DESCRIPTION FOR CARRYING OUT THE INVENTION

Generally stated, disclosed herein is a highly-efficient full van der Waals (vdW) 1D p-Te/2D n-Bi₂O₂Se heterodiodes with nanoscale ultra-photosensitive channels. Further, methods for making 1D Te nanowire/2D Bi₂O₂Se nanosheet heterojunction via a standard transfer process are disclosed.

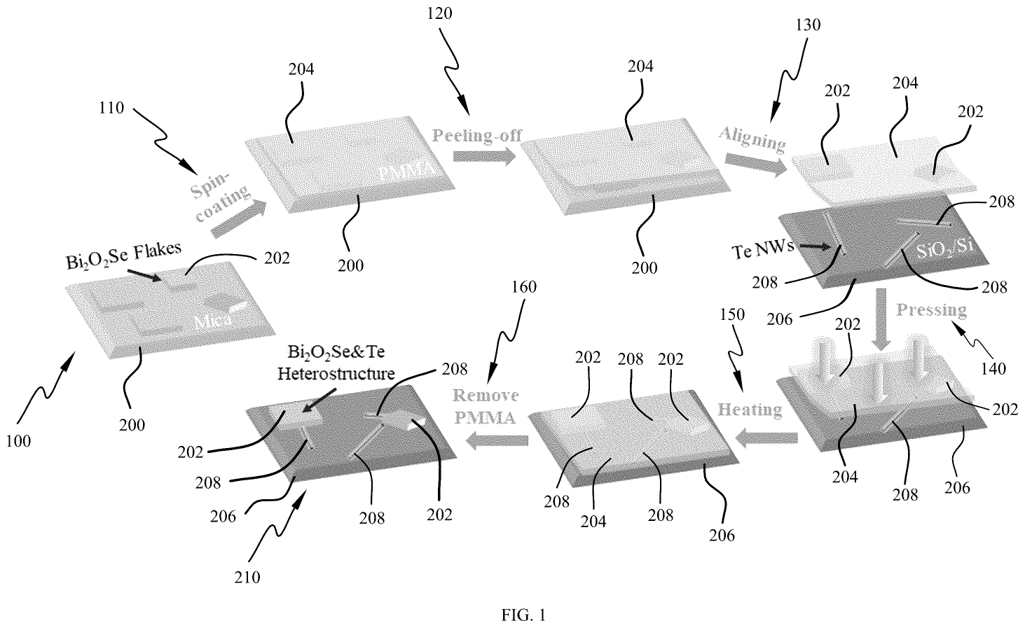

Referring to the drawings, wherein like reference numerals are used to indicate like or analogous components throughout the several views, and with particular reference to FIGS. 1-6C there is illustrated a highly-efficient full van der Waals (vdW) 1D p-Te/2D n-Bi₂O₂Se heterodiodes with nanoscale ultra-photosensitive channels and the method of fabricating the 1D Te nanowire/2D Bi₂O₂Se nanosheet heterojunction via a standard transfer process. The method may also include fabricating the electrodes of the p-Te/2D n-Bi₂O₂Se photodiodes.

A full van der Waals (vdWs) 1D p-Te/2D n-Bi₂O₂Se heterodiodes with a rationally-designed nanoscale ultra-photosensitive channel is developed. In these devices, both 1D Te nanowires (NWs) and 2D Bi₂O₂Se nanosheets (NSs) are fabricated by the chemical vapor deposition (CVD) method, and the full-vdWs Te/Bi₂O₂Se heterodiodes are constructed on 270 nm SiO₂/Si substrates. Due to the dangling-bond-free interface of the full-vdWs 1D p-Te/2D n-Bi₂O₂Se heterodiode, the defect-induced performance degradation of the devices is minimized, showing a recorded ratification ratio (RF) of 3.6×10⁴. The rationally designed nanoscale photosensitive channel of the optoelectronic devices optimizes the resistance-capacitance (RC) time constant, which has shown great potential to improve the response speed under low external potential. Moreover, the full-vdWs 1D p-Te/2D n-Bi₂O₂Se heterodiode show significant advantages in light absorption efficiency, as they generally demonstrate non-degradation of light absorption powered by the antenna effects of NWs. Herein, under a reverse bias of 100 mV, the device exhibits a high responsivity (R) of 130 A W⁻¹, a large detectivity (D*) of 2.5×10¹¹ Jones, and a fast response time down to 330 μs. Simultaneously, the well-aligned Type II heterojunctions endow self-powered photodetectors with a pronounced photovoltaic responsivity of 768.8 mA W⁻¹, a high light on/off ratio of 10+, and a fast response time of 400 μs. The full-vdWs 1D p-Te/2D n-Bi₂O₂Se heterodiode shows significant advances in fulfilling the downscaling requirements of the optoelectronic components for higher operation speed, better noise tolerance, and lower power consumption.

Referring now to FIG. 1, a method for fabricating 1D nanowires (NWs) and 2D nanosheets (NSs) by chemical vapor deposition (CVD) on mica (KMg₃AlSi₃O₁₀F₂) substrates, and the heterodiodes are constructed on substrates by a standard wet transfer process is shown. The method includes obtaining 100 a substrate 200 with nanosheets or flakes 202, for example, Bi₂O₂Se flakes or nanosheets on the substrate 200. Fabricating the Bi₂O₂Se nanosheets 202 may include high-crystallinity epitaxial growth. Next, the method includes spin coating 110 a layer or engineered plastic layer 204, for example, polymethyl methacrylate (PMMA), over the substrate 200. Then, the method includes peeling-off 120 the layer 204 from the substrate 200 to remove the coupled nanosheets 202. Next, the method includes obtaining a substrate 206 with nanowires 208 fabricated on the substrate 206. The nanowires 208 may be fabricated by high-crystallinity epitaxial growth. The method then includes the peeled-off layer 204 with coupled nanosheets 202 being aligned 130 with the substrate 206 including the nanowires 208. At least a portion of the nanosheets 202 are aligned with the nanowires 208. Once aligned, the method includes pressing 140 the peeled-off layer 204 to the substrate 206. Next, the method includes heating 150 the peeled-off layer 204 and substrate 206. After the heating is complete, the method includes removing 160 the layer 204 from the substrate 206 leaving the nanosheets 202 on the substrate 206 positioned over at least a portion of the nanowires 208 to form a fabricated device 210. The fabricated device 210 may include, for example, Bi₂O₂Se and Te heterostructures, as shown in FIG. 1.

With continued reference to FIG. 1, the heterostructures may include a nanosheet 202 at least partially overlapping a nanowire 208. For example, the heterostructures may have a Bi₂O₂Se nanosheet and a Te nanowire. The nanosheet 202 may have, for example, a width larger than the width of the nanowire 208. In addition, the nanosheet 202 may have, for example, a length shorter than the length of the nanowire 208. Further, the nanosheet 202 may at least partially overlap at least one nanowire 208. For example, the nanosheet 202 may overlap two nanowires 208 extending in different directions relative to a long axis of the nanosheet 202.

In one embodiment, as shown in FIG. 1, 1D Te nanowires (NWs) and 2D Bi₂O₂Se nanosheets (NSs) being fabricated by a chemical vapor deposition (CVD) method on mica (KMg₃AlSi₃O₁₀F₂) substrates, and the full-vdWs Te/Bi₂O₂Se heterodiodes are constructed on 270 nm SiO₂/Si substrates by a standard wet transfer process. Firstly, the as-grown Te NWs on mica are merged into anhydrous ethanol and underwent minor ultrasonication to obtain a uniform NW colloidal suspension, followed by drop-casted onto SiO₂/Si (270 nm thick thermal oxide) substrates. The as-grown Bi₂O₂Se NSs were next detached from mica to deionized water by a polymethyl methacrylate (PMMA)-assisted wet transfer method and further transferred to the top of Te NW on the SiO₂/Si substrate with the aid of a 2D multifunctional micromanipulation transfer system. After drying and removing PMMA in acetone, the source/drain regions of Bi₂O₂Se/Te heterojunction were patterned by standard electron-beam lithography, followed by thermal evaporation of 50 nm thick Au electrodes and a lift-off process.

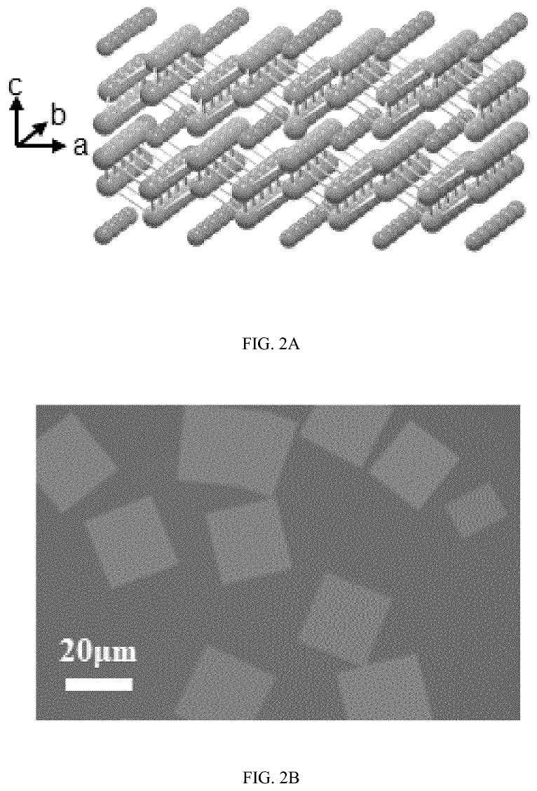

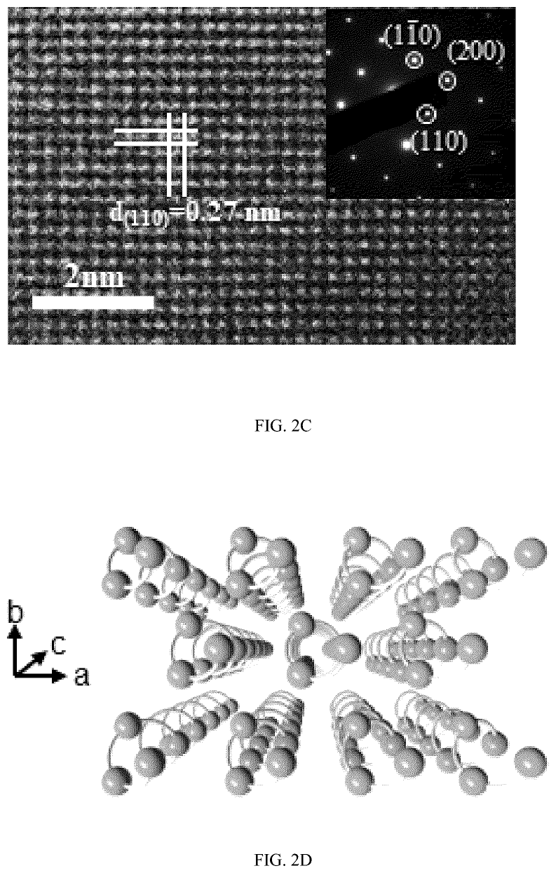

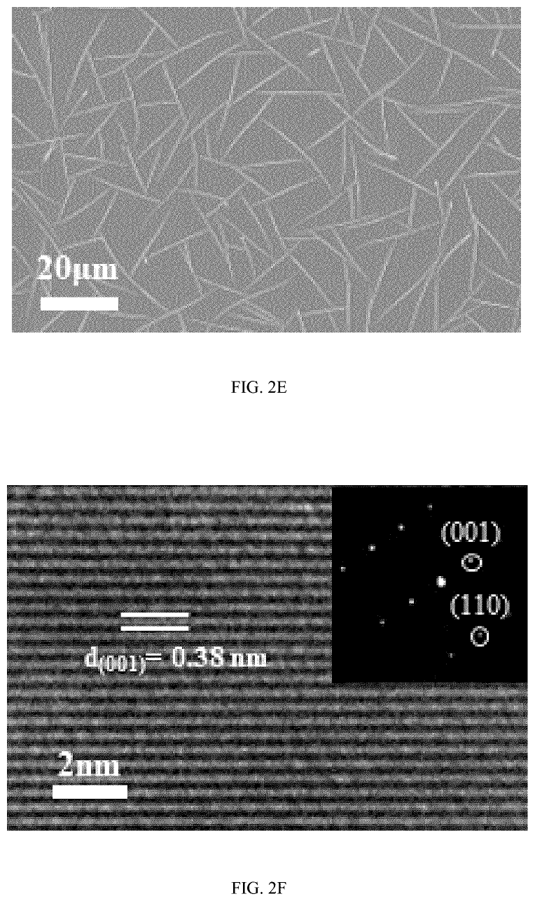

Referring now to FIGS. 2A-2F, the 1D p-Te/2D n-Bi₂O₂Se heterodiodes are shown. Before fabricating the 1D p-Te/2D n-Bi₂O₂Se heterodiodes, the crystallinity of these materials is tested. As shown in FIG. 2A, the Bi₂O₂Se NSs have a tetragonal crystal structure that is alternately stacked by [Bi₂O₂]ₙ²ⁿ⁺ and [Se]ₙ²ⁿ⁻ through the weak electrostatic interactions. FIG. 2B shows a scanning electron microscope (SEM) image of the as-grown CVD Bi₂O₂Se NSs. The CVD method is used to synthesize single-crystallinity Bi₂O₂Se nanosheets and Te nanowires on mica substrates. The high-resolution transmission electron microscopy (HRTEM) characterization of Bi₂O₂Se NSs suggests that the d-spacings of (110) planes are 0.27 nm, while its single-crystal nature is confirmed by the inset SAED pattern (FIG. 2C). As shown in FIG. 2D, Te NWs are covalently bonded atoms sequenced in a helical chain along a single axis, with chains packed in a hexagonal array via vdWs forces. The CVD-grown Te NWs show an excellent uniformity in diameters and lengths (FIG. 2E). The HRTEM image of Te NWs shows the interplanar spacing distances of around 0.2 nm, consistent with the lattice spacing of (001) planes of hexagonal Te crystals. The inset SEAD pattern shows the excellent single crystallinity of Te NWs.

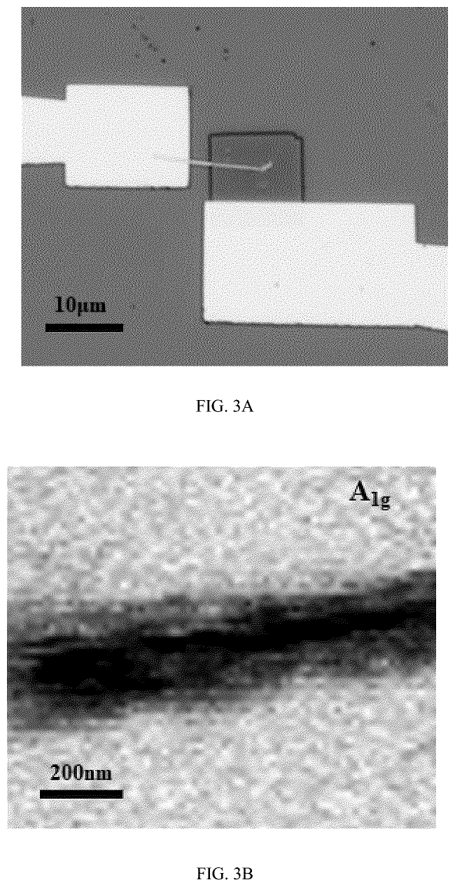

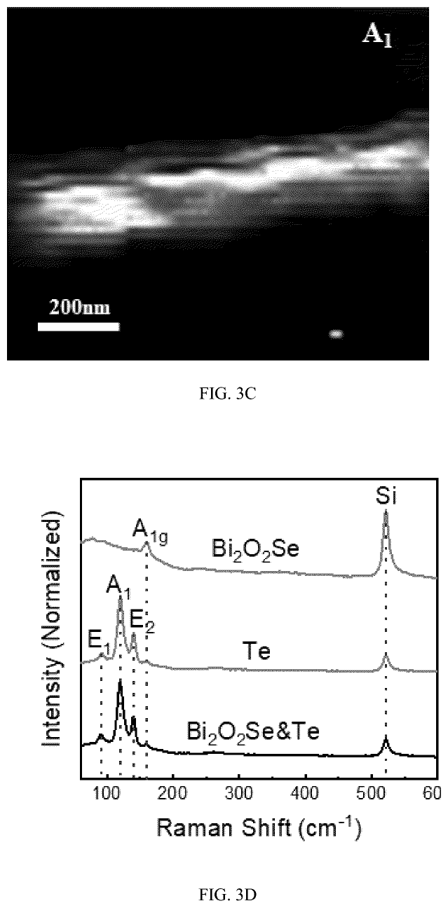

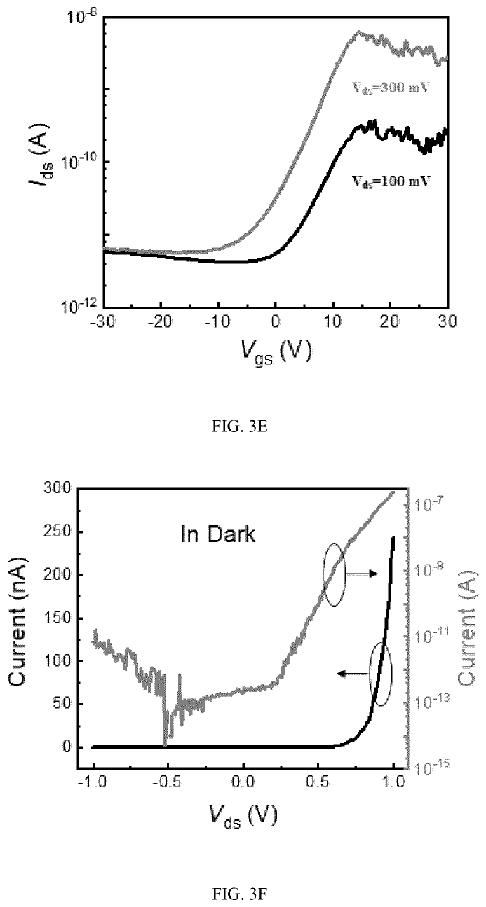

Referring now to FIGS. 3A-3F, images of the fabricated device and graphs of its properties are shown. FIG. 3A illustrates the optical microscope (OM) image of the fabricated device and FIG. 3B shows a schematic diagram of the corresponding device. In the heterojunction region, single helical chains of the Te NW are bonded by the weak vdWs force, and the interfacial atomic chains of Te NW are strongly-coupled with the Bi₂O₂Se NS through vdWs interaction with a narrow vdWs gap. Optical measurements across the heterojunction region may be taken to confirm the coupling effect and charge transfer phenomenon at the Te/Bi₂O₂Se heterojunction interface. The Raman spectra of pure Te, Bi₂O₂Se and the overlapped heterojunction are respectively presented in FIG. 3D. Three distinctive peaks of Te NWs are observed, including the most substantial Raman peak located at ˜121 cm⁻¹. This peak is associated with the A₁ mode, corresponding to the chain-expansion vibration of Te atoms along the basal plane. The other two peaks of E₁ mode (93 cm⁻¹) and E₂ (141 cm⁻¹) are observed, corresponding to the asymmetric bond-stretching along the c-axis and predominate bond-bending and bond-stretching types, respectively. In contrast, the vibration mode of Bi₂O₂Se located at ˜160 cm⁻¹ is assigned to the A_{1g} Raman peak. The Raman mappings of Bi₂O₂Se A_{1g} mode is shown in FIG. 3B and Te A₁ mode is shown in FIG. 3C further confirm the high crystallinity and excellent homogeneity of each component. There is no noticeable shift for all the characteristic peaks in the overlapped heterojunction region, confirming the high quality of the vdWs heterojunction obtained after the wet transfer processes. Apparently, the drastic Raman intensity reduction of the A_{1g} mode of Bi₂O₂Se is witnessed at the junction region, known as “Raman quenching”, indicating a strong interfacial coupling between the Te NWs and the Bi₂O₂Se NSs of the heterojunction devices.

When an n-type Bi₂O₂Se NS is stacked on top of a p-type Te NW, a type II staggered vdWs p-n junction is usually formed with the carrier transport showing antiambipolar-like characteristics swept from −30 to 30 V (FIG. 3e). FIG. 3F shows the current-voltage (I-V) curves of Te/Bi₂O₂Se heterojunction in linear and logarithmic scales with the source/drain bias range of −1 to 1V with zero gate voltage in the dark. This device shows a strong rectification behavior, with a calculated ideality factor of 1.9 based on the diffusion theory of Shochley. The rectification factor (RF) reaches up to 3.6×10⁴ under a slight bias of |V_{ds}|=1V.

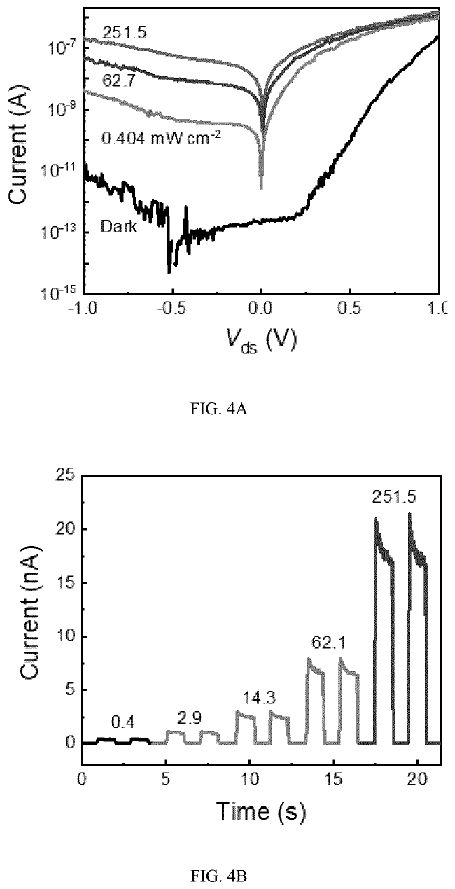

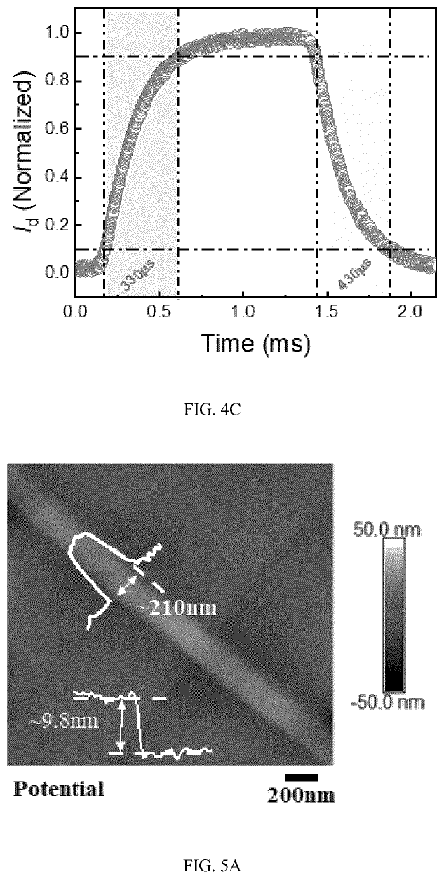

Referring now to FIGS. 4A-4C, show the photoelectronic properties of the heterojunction devices. The photoelectronic properties of the Te/Bi₂O₂Se heterojunction without gate voltage include excellent rectification behavior and ultralow reverse current (10⁻¹² A). For example, FIG. 4A illustrates the I_{ds}-V_{ds} curves on a logarithmic scale under different light intensities at 635 nm, 532 nm, and 405 nm, respectively. When a low reverse bias (V_{ds}=−100 mV) is applied in the dark, the device will work off-state with an ultralow reverse current. Whereas, under light irradiation, the photogenerated carriers (electrons and holes) can be effectively separated and transferred into distinct materials at the interface due to the enhanced interface potential barrier. Thus, a maximum on/off current ratio of 4.7×10⁴ (635 nm), 1.1×10⁵ (532 nm), and 1.6×10⁴ (405 nm) can be respectively achieved at a small negative bias (−100 mV). The photoswitching characteristics show in FIG. 4B that the photocurrent response continuously increases as the light intensity increases, which is consistent with the number of photogenerated carriers proportional to the incoming photon flux. Furthermore, the time-resolved photoresponse of the Te/Bi₂O₂Se heterojunction can be measured under different laser wavelengths, where the device exhibits a fast response speed of several hundred microseconds as shown in FIG. 4C. In particular, the device yields a fast rise time of 330 us and a decay time of 430 us under an illumination intensity of 251.5 mW/cm² at a 532 nm laser.

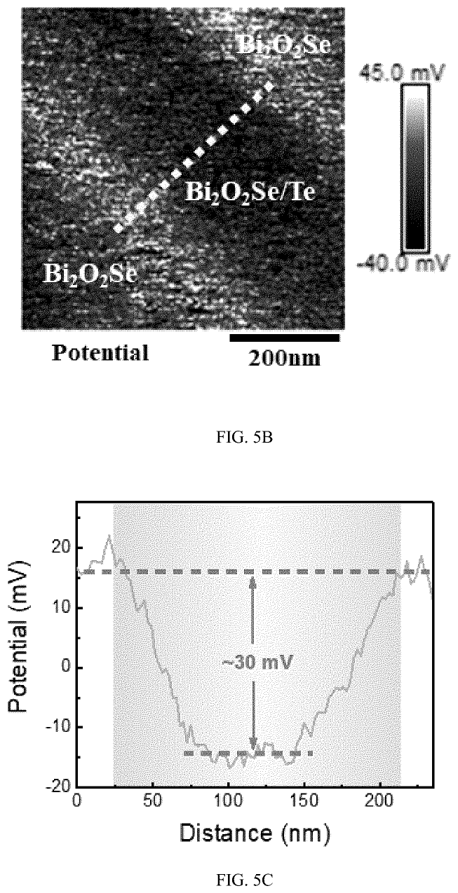

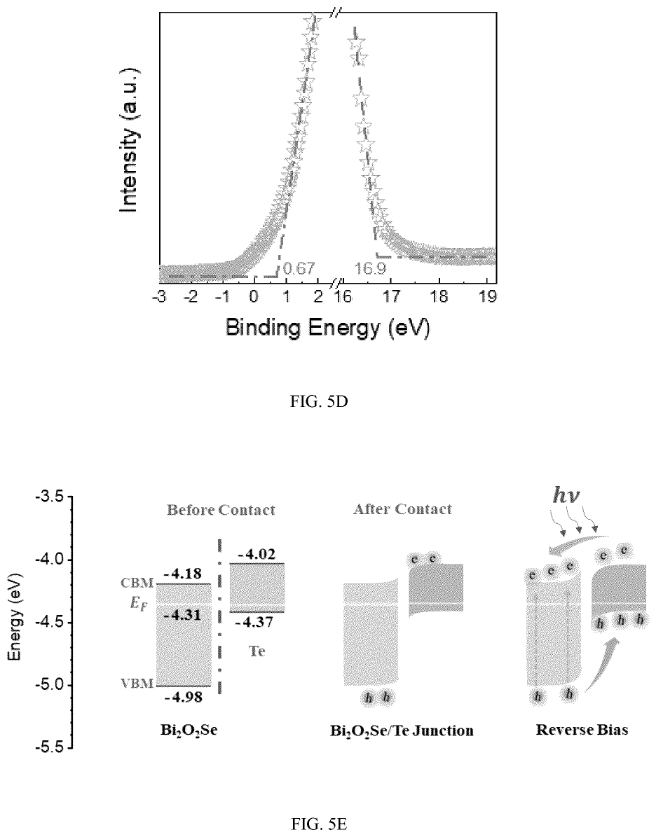

Referring now to FIGS. 5A-5E, images and graphs for assessing the energy band alignment of the heterojunction are shown. As the carrier transport behavior of the heterojunction is intrinsically determined by the band alignment, it is necessary to assess the energy band alignment of the heterojunction. Prior to this, the surface morphology of the heterojunction is characterized by the atomic force microscope (AFM), indicating that the diameter of the Te NW is ˜210 nm and the thickness of the Bi₂O₂Se NS is ˜9.8 nm (˜15 layers), as shown in FIG. 5A. The height profiles of the Te NW and the Bi₂O₂Se NS are shown in the inset of FIG. 5A. Typically, NWs with a small diameter of 100-300 nm would allow a nanowire cavity to interact with incident light beyond its projected incident area, resulting in the extended absorption and scattering cross-sections at desired wavelengths (a large refractive index contrast for strong light confinement). In addition, the sub-10 nm thickness of Bi₂O₂Se has been featured with excellent electron mobility at room temperature and the external quantum efficiency up to 230 cm² V⁻¹ s⁻¹ and 1.5×10⁷%, respectively. It is understood that with rationally-designed diameter/thickness, Te NWs combined with Bi₂O₂Se NSs would produce a relatively high light absorption efficiency, which is suitable for photoelectronic applications. Thus, the Kelvin probe force microscopy (KPFM) measurement can be used to reveal the Fermi level shift and determine the energy band alignment, as shown in FIG. 5B. The contact potential difference (CPD) between the probe and the sample is calculated by Equation 1.

$${V}_{CPD} = \frac{{W}_{T i p} - {W}_{Sample}}{e} \qquad Equation 1$$

Where W_{Tip} and W_{Sample} are the work function of the tip and the sample, respectively. The work function difference between Te NW and Bi₂O₂Se NS can be obtained by acquiring the V_{CPD} difference. According to the sectional profile of V_{CPD} and as shown in FIG. 5C, the V_{CPD} difference of the Te/Bi₂O₂Se heterojunction is calculated to be around 30 mV. Referring now to FIG. 5D, as characterized by ultraviolet photoelectron spectroscopy (UPS) of Bi₂O₂Se NSs, the work function (W) of Bi₂O₂Se is calculated as 4.3 eV by subtracting the second electron cut-off edge (16.9 eV) from the photon energy of the He I light source (21.21 eV). As shown in FIG. 5D, the valance band energy of the Bi₂O₂Se is determined to be 0.67 eV. Combining the above analysis and taking the bandgap of thin Bi₂O₂Se NSs and Te NWs to be 0.8 eV and 0.35 eV, respectively, a type II band alignment can be constructed before contact, as shown in FIG. 5E, left. When the two materials contact, the higher Fermi level of Bi₂O₂Se induces electrons to transfer to Te until reaching a thermal equilibrium state with an identical E_{F}, the leaving holes and electrons will accumulate at the Bi₂O₂Se and Te side, leading to the energy bands of Bi₂O₂Se sloping upwards toward the Te side and forming a built-in potential from Bi₂O₂Se to the Te side across the junction, as shown in FIG. 5E, middle. When applying a negative bias, the direction of the external electric field is identical to its built-in potential, as shown in FIG. 5E, right. The enhanced potential difference under a small bias can further promote the photoexcited electron-hole pairs separation, contributing to the photoconductivity-dominant responsivity mechanism.

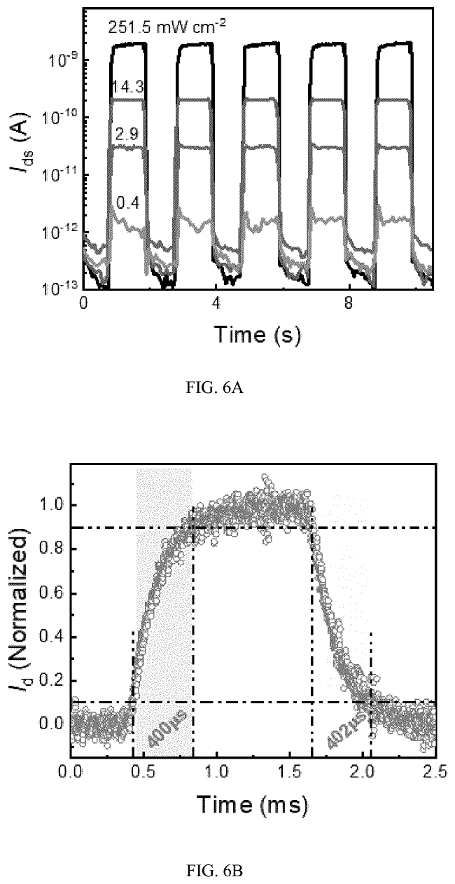

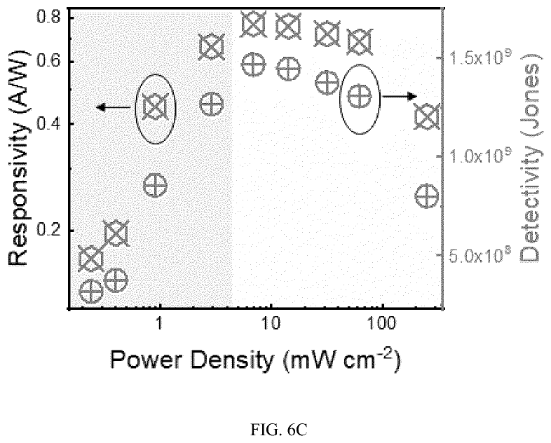

Referring now to FIGS. 6A-6C, additional graphs are illustrated showing further properties of the heterojunction devices. For example, these heterojunction devices can also be operated as self-powered photodetectors with zero bias by using the photovoltaic effect. Without consuming external power, these devices may become more reliable, meeting the requirements of energy-conserving photoelectronics for the low-carbon era. The photovoltaic properties of the heterojunctions devices may be investigated after systematically exploring the photoconductive effect of the heterojunction under a small bias. FIG. 6A shows the time-resolved photovoltaic response under 532 nm illumination of various power intensities. The photocurrent exhibits a remarkable and fast switching with a high on/off current ratio of 10⁴ and a fast response speed of ˜400 μs under zero bias, as shown in FIG. 6B, attributable to the strongly-coupled dangling-bond-free vdWs junction interface. Moreover, as illustrated in FIG. 6C, the device shows a pronounced photovoltaic responsivity of 768.8 mA W⁻¹ and a high detectivity of 1.5×10⁹ Jones at 6.9 mW/cm⁻². Overall, the heterodiode performs significantly better than many previously reported vdWs heterostructure photodetectors, specifically for photovoltaic applications.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has”, and “having”), “include” (and any form of include, such as “includes” and “including”), and “contain” (and any form of contain, such as “contains” and “containing”) are open-ended linking verbs. As a result, a method or device that “comprises,” “has,” “includes,” or “contains” one or more steps or elements possesses those one or more steps or elements, but is not limited to possessing only those one or more steps or elements. Likewise, a step of a method or an element of a device that “comprises,” “has,” “includes,” or “contains” one or more features possesses those one or more features, but is not limited to possessing only those one or more features. Furthermore, a device or structure that is configured in a certain way is configured in at least that way, but may also be configured in ways that are not listed.

The invention has been described with reference to the preferred embodiments. It will be understood that the architectural and operational embodiments described herein are exemplary of a plurality of possible arrangements to provide the same general features, characteristics, and general system operation. Modifications and alterations will occur to others upon a reading and understanding of the preceding detailed description. It is intended that the invention be construed as including all such modifications and alterations.

Having thus described the preferred embodiments, the invention is now claimed to be:

1. A method of forming heterodiodes, comprising:
obtaining a first substrate with at least one nanosheet;
spin-coating a layer over the substrate and at least one nanosheet;
peeling off the layer from the substrate removing the at least one coupled nanosheet and forming a peeled-off layer;
obtaining a second substrate with at least one nanowire fabricated on the second substrate;
aligning the peeled-off layer with the second substrate;
pressing the peeled-off layer to the second substrate;
heating the peeled-off layer and the second substrate; and
removing the peeled-off layer from the second substrate leaving the at least one nanosheet on the second substrate forming at least one heterostructure.

2. The method of claim 1, wherein aligning the peeled-off layer with the second substrate comprises:
aligning at least a portion of the nanosheet coupled to the peeled-off layer with the at least one nanowire on the second substrate.

3. The method of claim 1, wherein removing the peeled-off layer from the second substrate leaving the at least one nanosheet on the second substrate comprises:
leaving the at least one nanosheet on the second substrate positioned over at least a portion of the at least one nanowire.

4. The method of claim 1, wherein the first substrate is formed of Mica.

5. The method of claim 4, wherein the at least one nanosheet is made of bismuth oxyselenide (Bi₂O₂Se).

6. The method of claim 5, wherein the layer is made of polymethyl methacrylate.

7. The method of claim 6, wherein the second substrate is made of silicon dioxide/silicon.

8. The method of claim 7, wherein the at least one nanowire is made of tellurium.

9. The method of claim 8, wherein the at least one heterostructure is made of bismuth oxyselenide and tellurium.

10. The method of claim 9, wherein the at least one heterostructure comprises:
a nanowire; and
a nanosheet coupled to at least a portion of the nanowire.

11. The method of claim 1, further comprising:
detaching the at least one nanosheet from the first substrate by a wet transfer method.

12. The method of claim 1, further comprising:
dispersing at least one nanowire by minor ultrasonication.

13. The method of claim 1, wherein forming heterodiodes comprises chemical vapor deposition.

14. The method of claim 1, further comprising:
patterning source/drain regions of at least one heterostructure by standard electron-beam lithography.

15. The method of claim 1, further comprising:
detaching the at least one nanosheet and the at least one nanowire using a PMMA solution and liquid anhydrous ethanol.

16. A 1D p-Te/2D n-Bi₂O₂Se heterodiode, comprising:
a nanowire; and
a nanosheet positioned over at least a portion of the nanowire.

17. The heterodiode of claim 16, wherein the nanowire is made of tellurium.

18. The heterodiode of claim 16, wherein the nanosheet is made of bismuth oxyselenide (Bi₂O₂Se).

19. The heterodiode of claim 16, wherein a width of the nanowire is smaller than a width of the nanosheet.

20. The heterodiode of claim 16, wherein a length of the nanowire is larger than a length of the nanosheet.
